(19) United States
(12) Patent Application Publication
(10) Pub. No.: US 2025/0258439 A1
(43) Pub. Date: Aug. 14, 2025

(54) A LITHOGRAPHIC APPARATUS, AN INSPECTION SYSTEM, AND A DETECTOR HAVING A SQUARE-CORE FIBER

(71) Applicant: ASML Netherlands B.V., Veldhoven (NL)

(72) Inventors: Mahesh Upendra AJGAONKAR, Guilford, CT (US); Aniruddha Ramakrishna SONDE, Stamford, CT (US); Krishanu SHOME, Cheshire, CT (US)

(73) Assignee: ASML Netherlands B.V., Veldhoven (NL)

(21) Appl. No.: 18/856,459

(22) PCT Filed: Mar. 30, 2023
(86) PCT No.: PCT/EP2023/058252

§ 371 Date: Oct. 11, 2024

Related U.S. Application Data
(60) Provisional application No. 63/331,759, filed on Apr. 15, 2022.

(51) Int. Cl. G03F 7/00

(52) U.S. Cl. CPC G03F 7/70633; G03F 7/706849; G03F 7/706851; G03F 7/7085

(57) ABSTRACT

An apparatus includes an illumination system, a projection system, and an inspection system. The illumination system illuminates a pattern of a patterning device. The projection system projects an image of the pattern onto a substrate. The inspection system includes a radiation source, an optical element, and a detector. The radiation source generates radiation. The optical element directs the radiation toward a target on the substrate. The detector includes a photosensitive device and a squarecore optical fiber. The photosensitive device receives at least a portion of radiation scattered by the target and generates a measurement signal based on the received portion of the radiation. The squarecore optical fiber is coupled to the photosensitive device, guides the portion of the radiation to the photosensitive device, and homogenizes the guided portion of the radiation such that an intensity cross-section of the received portion of the radiation at the photosensitive device is approximately uniform.

### CROSS-REFERENCE TO RELATED APPLICATIONS

This application claims priority of U.S. application 63/331,759 which was filed on Apr. 15, 2022 and which is incorporated herein in its entirety by reference.

### FIELD

The present disclosure relates to detectors, for example, a detector of an inspection system used for wafer alignment measurements in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Ideally, a detector of an inspection system would have a stable and predictable response to the photons incident on its face (e.g., signal linearly proportional to the number of incident photons). However, in practice, detectors have a nonlinear response to incident radiation. The nonlinear response can be due to microscopic imperfections arising from the manufacture process of the detectors and/or absorption nonlinearity in the material of the detectors. Intensity fluctuations due to the nonlinearity of the detector can contribute to uncertainty of the measurements performed by the inspection system.

### SUMMARY

Accordingly, embodiments described herein address uncertainty of measurements arising from nonlinear detector response.

In some embodiments, an apparatus can comprise an illumination system, a projection system, and an inspection system. The illumination system can be configured to illuminate a pattern of a patterning device. The projection system can be configured to project an image of the pattern onto a substrate. The inspection system can comprise a radiation source, an optical element, and a detector. The radiation source can be configured to generate radiation. The optical element can be configured to direct the radiation toward a target on the substrate. The detector can comprise a photosensitive device and a square-core optical fiber. The photosensitive device can be configured to receive at least a portion of radiation scattered by the target and to generate a measurement signal based on the received portion of the radiation. The square-core optical fiber can be coupled to the photosensitive device and can be configured to guide the portion of the radiation to the photosensitive device and to homogenize the guided portion of the radiation such that an intensity cross-section of the received portion of the radiation at the photosensitive device is approximately uniform.

In some embodiments, an inspection system can comprise a radiation source, an optical element, and a detector. The radiation source can be configured to generate radiation. The optical element can be configured to direct the radiation toward a target. The detector can comprise a photosensitive device and a square-core optical fiber. The photosensitive device can be configured to receive at least a portion of radiation scattered by the target and to generate a measurement signal based on the received portion of the radiation. The square-core optical fiber can be coupled to the photosensitive device and can be configured to guide the portion of the radiation to the photosensitive device and to homogenize the guided portion of the radiation such that an intensity cross-section of the received portion of the radiation at the photosensitive device is approximately uniform.

In some embodiments, a detector can comprise a photosensitive device and a square-core optical fiber. The photosensitive device can be configured to receive radiation and to generate a measurement signal based on the received radiation. The square-core optical fiber can be coupled to the photosensitive device and can be configured to guide the radiation to the photosensitive device and to homogenize the guided radiation such that an intensity cross-section of the received radiation at the photosensitive device is approximately uniform.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of inspection apparatuses, according to some embodiments.

FIG. 5 shows a detection portion of an inspection system, according to some embodiments.

FIG. 6A shows a radiation spot with a speckle pattern, according to some embodiments.

FIG. 6B shows a graph of intensity data of the speckle pattern in FIG. 6A, according to some embodiments.

FIG. 7A shows an output facet of a square-core optical fiber, according to some embodiments.

FIG. 7B shows a two-dimensional intensity map of radiation output from the facet of FIG. 7A, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

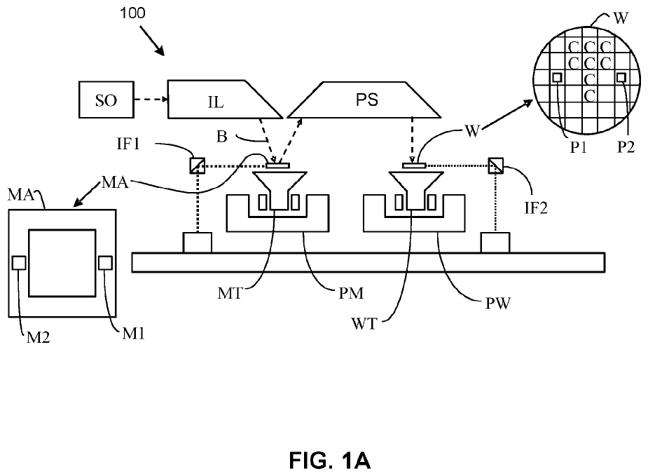

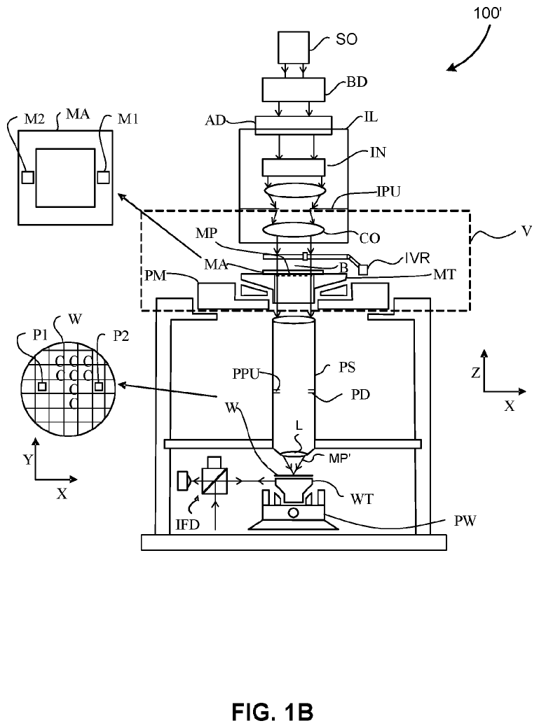

FIGS. 1A and 1B show schematic illustrations of a lithographic apparatus 100 and lithographic apparatus 100′, respectively, in which embodiments of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The terms “inspection apparatus,” “metrology system,” or the like can be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. The source

SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “o-outer” and “o-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first-and higher-order diffracted beams (not shown). In some embodiments, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration can be reduced by providing radiation poles (not shown) in opposite quadrants of the illumination system pupil IPU. Further, in some embodiments, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

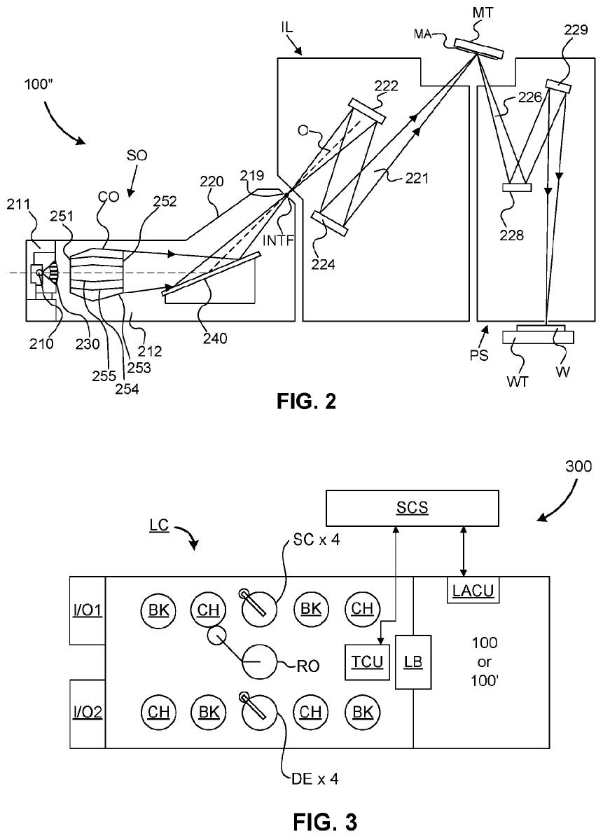

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor can be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Exemplary Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

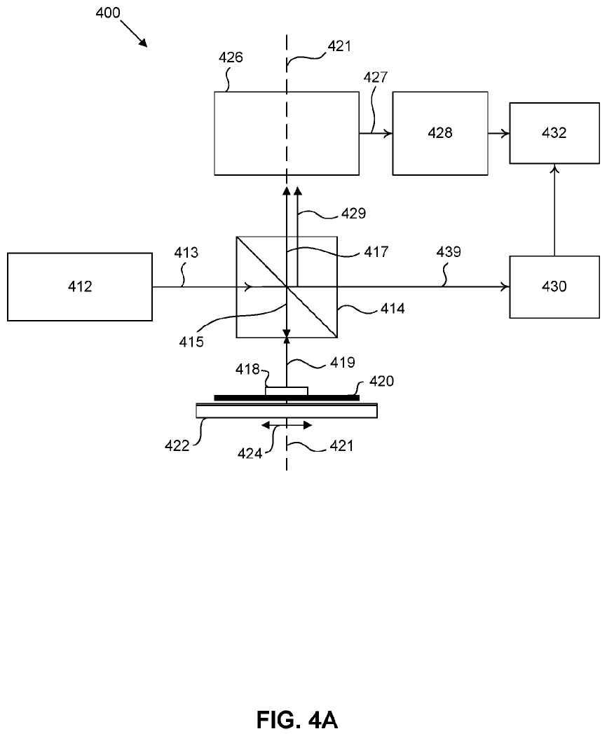

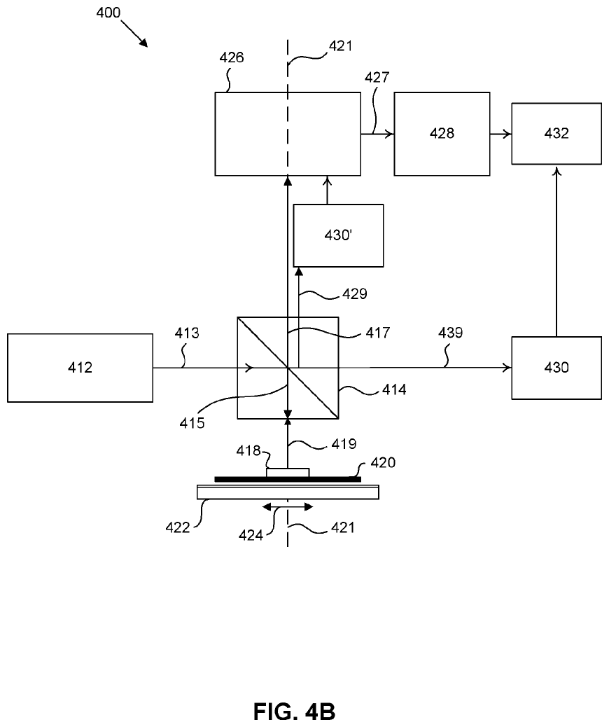

FIG. 4A shows a schematic of a cross-sectional view of an inspection apparatus

400 that can be implemented as a part of lithographic apparatus 100 or 100′, according to some embodiments. In some embodiments, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

In some embodiments, inspection apparatus 400 can include an illumination system 412, a beam splitter 414, an interferometer 426, a detector 428, a beam analyzer 430, and a processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some embodiments, alignment mark or target 418 can have one hundred and eighty degrees (i.e.,) 180° symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating.

In some embodiments, beam splitter 414 can be further configured to receive diffraction radiation beam 419 and split diffraction radiation beam 419 into at least two radiation sub-beams, according to an embodiment. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that can be reflected from alignment mark or target 418. In an example of this embodiment, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can for example be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or ATHENA (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some embodiments, beam analyzer 430 can be directly integrated into inspection apparatus 400, or connected via fiber optics of several types: polarization preserving single mode, multimode, or imaging, according to other embodiments.

In some embodiments, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some embodiments, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some embodiments, second beam analyzer 430′ can be directly integrated into inspection apparatus 400, or it can be connected via fiber optics of several types: polarization preserving single mode, multimode, or imaging, according to other embodiments. Alternatively, second beam analyzer 430′ and beam analyzer 430 can be combined to form a single analyzer (not shown) configured to receive and determine the optical states of both diffracted radiation sub-beams 429 and 439.

### Exemplary Detector With Square-Core Fiber

It is instructive to first consider some issues in the state of the art. As nanofabrication technology has evolved, printed devices have been reduced to extremely small sizes. In the past, micron scale devices demanded alignment precision in the order of microns. Alignment devices having uncertainties in the range of, for example, tens of nanometers would have been negligible for the purposes of micron scale fabrication. However, with devices now reaching sub-nanometer scales, even the smallest fluctuations of a signal from a detector can produce errors that severely increase failure rates of sub-nanometer printed devices (e.g., errors in the range of picometers). Embodiments described herein can reduce non-linear fluctuations of measurement signals and, therefore, increase accuracy of lithographic pattern transfers and reduce instances of fabrication failure.

Next, a brief overview is provided for how a measurement signal can be analyzed when performing an alignment measurement. In some embodiments, target is 418 can be irradiated with illumination radiation to generate scattered radiation. The scattered radiation can have one or more diffraction orders (e.g., ±1, ±2, or the like). The diffraction orders can be collected and sent to detector 428 (or a plurality of detectors). Detector 428 can generate measurement information in the form of a signal (e.g., a measurement signal). The measurement signal can be analyzed by a processor to determine a relative position of target 418 (e.g., a wafer alignment position), overlay offset, or the like. In the case of an alignment measurement, detector 428 can be a single-cell detector (i.e., a single pixel detector), a multi-pixel detector (e.g., a camera) capable of resolving an image, or the like. An alignment position can be inferred by analyzing a total intensity on a detector without having to analyze individual pixel intensities. For example, an alignment measurement can involve modulating the illumination (e.g., sinusoidal intensity with respect to time) and then analyzing characteristics of the AC signal generated by the detector (e.g., amplitude, phase, or the like). An alignment position of target 418 can be derived from the characteristics of the AC signal. And the analysis can be accomplished whether a single-pixel detector or a camera is used.

In some embodiments, an optical fiber can be used for collecting radiation scattered from target 418 and guiding the radiation directly to a photosensitive element of detector 428. The optical fiber implementation can maximize the number of photons collected. An optical fiber can be more compact and convenient than free space optics that uses lenses and/or mirrors. The output end of the optical fiber can be affixed to the photosensitive element of detector 428.

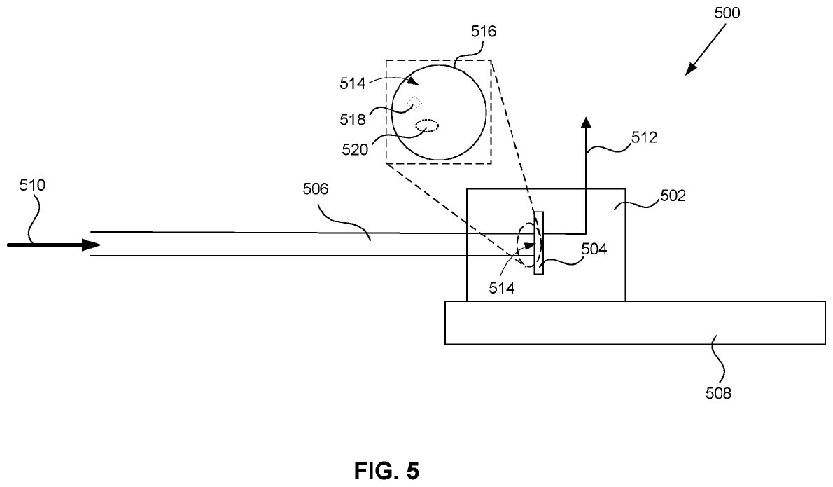

FIG. 5 shows a detection portion of an inspection system 500, according to some embodiments. In some embodiments, inspection system 500 can comprise a detector 502. Detector 502 can be used as detector 428 in FIGS. 4A and 4B. Detector 502 can be disposed on a board 508 (e.g., a circuit board, digital board, or the like). Detector 502 can comprise a photosensitive device 504 and an optical fiber 506. Optical fiber 506 can be coupled to photosensitive device 504 using, for example, index-matching adhesive, a fiber connector (e.g., pigtail connector), or the like. Board 508 can comprise a corresponding optical fiber connector such that optical fiber 506 can be coupled to the connector on board 508 to achieve optical coupling of optical fiber 506 and photosensitive device 504. Optical fiber 506 can receive radiation 510. Radiation 510 can be radiation that has been scattered by a target (e.g., radiation scattered by target 418, diffraction radiation beam 419, diffraction sub-beam 429, or the like (FIG. 4)) and guide it to photosensitive device 504. Photosensitive device 504 can generate a measurement signal 512 in accordance with the radiation that is incident on the face 514 of photosensitive device 504. Measurement signal 512 may be an electrical signal (e.g., a voltage signal, a current signal, or the like).

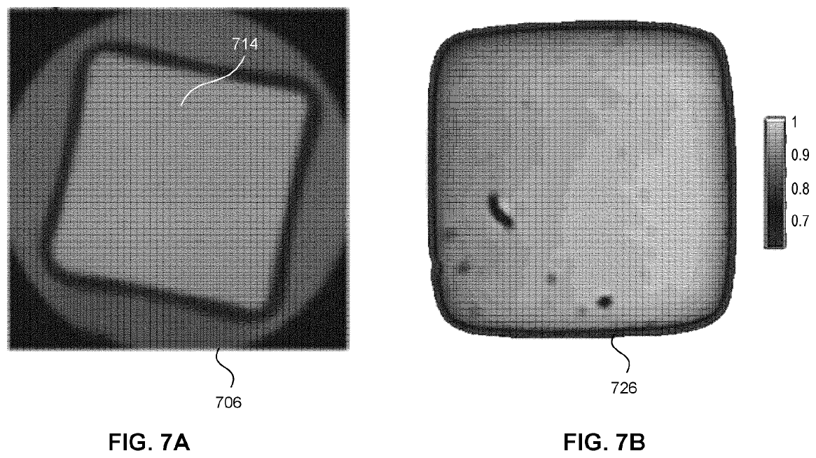

In some embodiments, optical fiber 506 can a step-index fiber or a gradient-index fiber. In some embodiments, optical fiber 506 in comprise a square-core optical fiber, which will be described in more detail in reference to FIG. 7. Optical fiber 506 can allow approximately lossless transmission of a plurality of wavelengths of the received radiation. For an inspection system, the wavelengths can comprise two or more wavelengths. The chosen wavelengths can comprise any permutation of red, green, near infrared (NIR), and far infrared (FIR) wavelengths. Red wavelength can be understood to be in the range of approximately 620 to 770 nm. Green wavelength can be understood to be in the range of approximately 490 to 570 nm. NIR wavelength can be understood to be in the range of approximately 780 nm to 2500 nm. FIR wavelength can be understood to cover the range beyond NIR, out to approximately 1 mm.

In some embodiments, the single photosensitive device 504 and optical fiber 506 combination shown in FIG. 5 is provided as a non-limiting example. Additional detectors 502 are envisaged (e.g., second detector, third detector, etc.) (additional detectors not shown for clarity of picture). In one example, inspection system 500 with a plurality of detectors 502 can dedicate each detector to a given wavelength. In another example, a plurality of detectors 502 can be dedicated to different diffraction orders coming from target 418 (FIGS. 4A and 4B). Wavelengths and/or diffraction orders may be separated using optical devices such as beam splitters, demultiplexers, filters, refraction, or the like, as would become apparent to those skilled in the art.

It should be appreciated that, in some embodiments, enumerative adjectives (e.g., “first,” “second,” “third,” or the like) can be used as a naming convention and are not intended to indicate an order or hierarchy (unless otherwise noted). For example, the terms a first detector” and a “second detector” can distinguish two detectors, but need not specify if the detectors have a particular order or hierarchy. Furthermore, an element in a drawing is not limited to any particular enumerative adjective. For example, detector 502 can be referred to as a second detector if other detector(s) use appropriately distinguishing enumerative adjective(s).

In some embodiments, photosensitive device 504 can have a stable and predictable response to the photons incident on its face (e.g., signal linearly proportional to the number of incident photons). However, in some embodiments, photosensitive device 504 may have a nonlinear response to incident radiation. To illustrate an example, a radiation spot 516 incident on face 514 can have a 100-micron diameter (non-limiting example). A region 518 of photosensitive device 504 within illumination spot 516 can have an optical response that is different from an optical response of another region 520 of photosensitive device 504, despite best efforts by manufacturers to provide a device that has a uniform response. Microscopic imperfections are common in the manufacture of photosensitive devices.

In some embodiments, the problem with nonlinear optical behavior photosensitive device 504 would not be so detrimental if radiation spot 516 had a uniform intensity throughout its area. However, since an alignment measurement is a dynamic process (e.g., scan a radiation beam across a grating of target 418 to produce an AC signal), radiation spot 516 may not be perfectly uniform throughout a measurement. The problem may be exacerbated if coherent radiation is used for sourcing the radiation beam because self-interfering coherent radiation can produce speckle patterns in the illumination cross section.

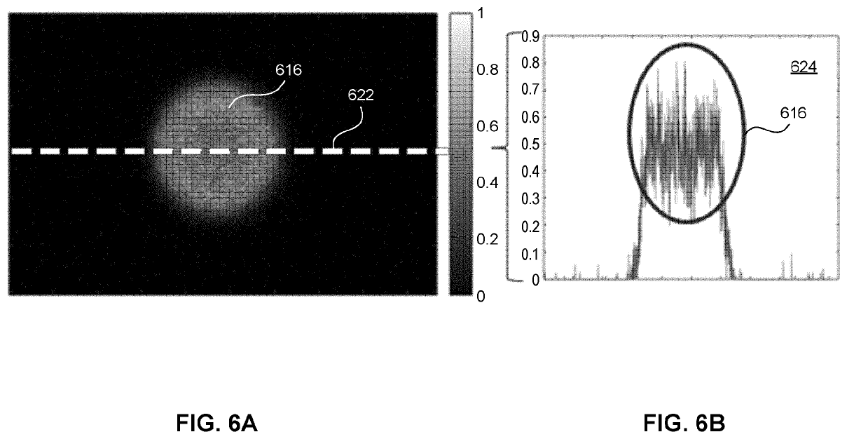

FIG. 6A shows a radiation spot 616, according to some embodiments. In some embodiments, FIG. 6A is a two-dimensional intensity map of radiation spot 616, with the intensity scale going from darker/black (low intensity) to brighter/white (high intensity). The intensity map shows that radiation spot 616 has a speckle pattern. Line 622 corresponds to the “slice” of intensity data illustrated in FIG. 6B. A type of optical fiber that can produce the intensity pattern of FIG. 6 can be, for example, a standard round-core optical fiber.

FIG. 6B shows a graph 624 of the speckle pattern at line 622, according to some embodiments. The circled emphasis corresponds to the intensity of radiation spot 616. The intensity fluctuations correspond to a speckle pattern of line 622 of the intensity cross-section. Considering the mean intensity of radiation spot 616, the 3 σ (i.e., three standard deviation (sigma) rule) can easily be estimated to be quite high. Dividing 3 σ by the mean can yield a quantity that is similar to a coefficient of variation (CV) (e.g., CV=σ/mean). For the data shown in FIG. 6, 3 σ/mean is approximately 0.7, which indicates a high amount of relative variance (i.e., the intensity distribution is not flat). Different sensitive regions 518 and 520 (FIG. 5) that receives such unpredictable radiation would correspondingly generate noisy measurement signals that can affect the accuracy when determining an alignment position.

In some embodiments, a measurement (e.g., an alignment measurement) can generate a measurement signal that behaves according to a modulation of the intensity of radiation spot 616 (e.g., bright to dark, dark to bright, sinusoidal modulation, or the like). A characteristic of the modulation (e.g., phase) can be used to infer a position of target 418 (FIG. 4). If the phase is noisy due to speckling in the detected radiation, the determined position will also have a large uncertainty. The excess phase noise can be caused by the conversion of optical intensity noise into electrical phase noise due to the phase nonlinearity of photosensitive device 504, characterized by its power-to-phase conversion factor (e.g., units can be expressed in degrees of phase per unit power). Additional information on power-to-phase conversion factors can be found in, for example, Joshi, A., & Datta, S. (2009), Dual InGaAs photodiodes having high phase linearity for precise timing applications, IEEE Photonics Technology Letters, 21(19), 1360-1362, which is incorporated by reference herein in its entirety.

In some embodiments, detector 502 with a step-index fiber can have a power-to-phase conversion factor of approximately 1-15 rad/W (e.g., 5 rad/W). Assuming a power-to-phase conversion factor of 5 rad/W and target 418 (FIG. 4) having a grating pitch of 1.6-3.2 microns, this translates to the measured position of target 418 (FIG. 4) having an uncertainty of approximately 0.15-0.29 nm, which is not negligible when fabricating sub-nanometer devices.

In some embodiments, the above-noted issues of position uncertainty can be solved by re-designing detector 502 or changing its operating principle, but such a solution has the drawback of being costly as well as possibly negating backwards compatibility with existing systems. Another solution can be to reduce speckling by implementing changes to the optics.

The inventors have overcome such drawbacks by employing a square-core optical fiber. FIG. 7A shows an output facet 714 of a square-core optical fiber 706, according to some embodiments. FIG. 7B shows a two-dimensional intensity map 726 of radiation output at facet 714. The intensity scale goes from darker/black (low intensity) to brighter/white (high intensity). Intensity map 726 shows that facet 714 can output radiation that is much more uniform when compared to the speckle of radiation spot 616 (FIG. 6) from a standard round-core optical fiber.

In some embodiments, by providing a more uniform intensity cross-section to be incident on photosensitive element 504 (FIG. 5), nonlinear response can be suppressed. Rather than speckle patterns being incident on different sensitive regions 518 and 520 (FIG. 5), the radiation incident on these regions is relatively constant, thereby mitigating an unpredictable disparity in response.

In some embodiments that implement square-core fiber 706, a power-to-phase conversion factor of detector 502 (FIG. 5) can be reduced to less than approximately 1 rad/W, 0.8 rad/W, 0.5 rad/W, or 0.3 rad/W. Implementations using square-core fiber 706 can be compatible with standard connector schemes (e.g., pigtail). Square-core fiber 706 can save on redesign costs and space usage (device footprint), as well as being more viable for retrofitting existing systems.

In some embodiments, providing a square-core fiber with a long length can enhance the homogenizing effect. Square-core fiber 706 can have a length that is approximately 1-100 m, 1-50 m, 1-20 m, 1-10 m, 1-5 m, 1 m, 5 m, or 10 m. Square-core fiber 706 can have a core size (e.g., diameter) that is approximately 10-600 microns. The core of square-core fiber 706 can be made of pure silica. The silica can comprise one more dopants (e.g., fluorine, germanium, or the like). A numerical aperture (NA) of square-core fiber 706 can be approximately 0.15 or greater (e.g., 0.16-0.39).

The embodiments may further be described using the following clauses:
1. An apparatus comprising:
   an illumination system configured to illuminate a pattern of a patterning device;
   a projection system configured to project an image of the pattern onto a substrate; and
   an inspection system comprising:
   a radiation source configured to generate radiation;
   an optical element configured to direct the radiation toward a target on the substrate; and
   a detector comprising:
   a photosensitive device configured to receive at least a portion of radiation scattered by the target and to generate a measurement signal based on the received portion of the radiation; and
   a square-core optical fiber coupled to the photosensitive device and configured to guide the portion of the radiation to the photosensitive device and to homogenize the guided portion of the radiation such that an intensity cross-section of the received portion of the radiation at the photosensitive device is approximately uniform.
2. The apparatus of clause 1, wherein the square-core optical fiber is further configured to allow approximately lossless transmission of a plurality of wavelengths of the received portion of the radiation.
3. The apparatus of clause 1, wherein:
   the inspection system comprises a digital board; and
   the detector is disposed on the digital board.
4. The apparatus of clause 3, wherein:
   the digital board comprises an optical fiber connector;
   the square-core optical fiber comprises an optical fiber connector; and
   the optical fiber connectors of the digital board and the square-core optical fiber are configured to mate to achieve the coupling of the square-core optical fiber and the photosensitive device.
5. The apparatus of clause 1, wherein the inspection system comprises a second detector comprising:
   a second photosensitive device configured to receive a second portion of the radiation scattered by the target and to generate a measurement signal based on the received second portion of the radiation; and
   a square-core optical fiber coupled to the photosensitive device and configured to guide the second portion of the radiation to the photosensitive device and to homogenize the guided second portion of the radiation such that an intensity cross-section of the received second portion of the radiation at the second photosensitive device is approximately uniform.
6. The apparatus of clause 1, wherein a power-to-phase conversion factor of the detector is less than approximately 1 rad/W.
7. The apparatus of clause 1, wherein the square-core optical fiber has a length of approximately 1-100 m, 1-50 m, 1-20 m, 1-10 m, 1-5 m, 1 m, 5 m, or 10 m.
8. An inspection system comprising:
   a radiation source configured to generate radiation;
   an optical element configured to direct the radiation toward a target; and
   a detector comprising:
   a photosensitive device configured to receive at least a portion of radiation scattered by the target and to generate a measurement signal based on the received portion of the radiation; and
   a square-core optical fiber coupled to the photosensitive device and configured to guide the portion of the radiation to the photosensitive device and to homogenize the guided portion of the radiation such that an intensity cross-section of the received portion of the radiation at the photosensitive device is approximately uniform.
9. The inspection system of clause 8, wherein the square-core optical fiber is further configured to allow approximately lossless transmission of a plurality of wavelengths of the received portion of the radiation.
10. The inspection system of clause 8, wherein:
   the inspection system comprises a digital board; and
   the detector is disposed on the digital board.
11. The inspection system of clause 10, wherein:
   the board comprises an optical fiber connector;
   the square-core optical fiber comprises an optical fiber connector; and
   the optical fiber connectors of the board and the square-core optical fiber are configured to mate to achieve the coupling of the square-core optical fiber and the photosensitive device.
12. The inspection system of clause 8, further comprising a second detector comprising:
   a second photosensitive device configured to receive a second portion of the radiation scattered by the target and to generate a measurement signal based on the received second portion of the radiation; and
   a square-core optical fiber coupled to the photosensitive device and configured to guide the second portion of the radiation to the photosensitive device and to homogenize the guided second portion of the radiation such that an intensity cross-section of the received second portion of the radiation at the second photosensitive device is approximately uniform.
13. The inspection system of clause 8, wherein a power-to-phase conversion factor of the detector is less than approximately 1 rad/W.
14. The inspection system of clause 8, wherein the square-core optical fiber has a length of approximately 1-100 m, 1-50 m, 1-20 m, 1-10 m, 1-5 m, 1 m, 5 m, or 10 m.
15. A detector comprising:
   a photosensitive device configured to receive radiation and to generate a measurement signal based on the received radiation; and
   a square-core optical fiber coupled to the photosensitive device and configured guide the radiation scattered by the target to the photosensitive device and to homogenize the guided radiation such that an intensity cross-section of the received radiation at the photosensitive device is approximately uniform.
16. The detector of clause 15, wherein the square-core optical fiber is further configured to allow approximately lossless transmission of a plurality of wavelengths of the received radiation.
17. The detector of clause 15, wherein the detector is disposed on the digital board.
18. The detector of clause 17, wherein:
   the digital board comprises an optical fiber connector;
   the square-core optical fiber comprises an optical fiber connector; and
   the optical fiber connectors of the digital board and the square-core optical fiber are configured to mate to achieve the coupling of the square-core optical fiber and the photosensitive device.
19. The detector of clause 15, wherein a power-to-phase conversion factor of the detector is less than approximately 1 rad/W.
20. The detector of clause 15, wherein the square-core optical fiber has a length of approximately 1-100 m, 1-50 m, 1-20 m, 1-10 m, 1-5 m, 1 m, 5 m, or 10 m.

Although specific reference can be made in this text to the use of lithographic apparatus in the manufacture of ICs, it should be understood that the lithographic apparatus described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein can also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam of radiation” or the like as used herein can encompass all types of electromagnetic radiation, for example, ultraviolet (UV) radiation (for example, having a wavelength 2 of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light,” “illumination,” or the like can refer to non-matter radiation (e.g., photons, UV, X-ray, or the like).

Generally, radiation having wavelengths between about 400 to about 700 nm is considered visible radiation; radiation having wavelengths between about 780-3000 nm (or larger) is considered infrared (IR) radiation. Infrared can be further subcategorized into a short wavelength portion (near infrared (NIR)) and a long wavelength portion (far infrared (FIR)). UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

It is to be appreciated that the Detailed Description section, and not the Summary and Abstract sections, is intended to be used to interpret the claims. The Summary and Abstract sections can set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure can be practiced otherwise than as described. The descriptions are intended to be illustrative, not limiting. Thus it will be apparent to one skilled in the art that modifications can be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. An apparatus comprising:
an illumination system configured to illuminate a pattern of a patterning device;
a projection system configured to project an image of the pattern onto a substrate; and
an inspection system comprising:
a radiation source configured to generate radiation;
an optical element configured to direct the radiation toward a target on the substrate; and
a detector comprising:
a photosensitive device configured to receive at least a portion of radiation scattered by the target and to generate a measurement signal based on the received portion of the radiation; and
a square-core optical fiber coupled to the photosensitive device and configured to guide the portion of the radiation to the photosensitive device and to homogenize the guided portion of the radiation such that an intensity cross-section of the received portion of the radiation at the photosensitive device is approximately uniform.

2. The apparatus of claim 1, wherein the square-core optical fiber is further configured to allow approximately lossless transmission of a plurality of wavelengths of the received portion of the radiation.

3. The apparatus of claim 1, wherein:
the inspection system comprises a digital board; and
the detector is disposed on the digital board.

4. The apparatus of claim 3, wherein:
the digital board comprises an optical fiber connector;
the square-core optical fiber comprises an optical fiber connector; and
the optical fiber connectors of the digital board and the square-core optical fiber are configured to mate to achieve the coupling of the square-core optical fiber and the photosensitive device.

5. The apparatus of claim 1, wherein the inspection system comprises a second detector comprising:
a second photosensitive device configured to receive a second portion of the radiation scattered by the target and to generate a measurement signal based on the received second portion of the radiation; and
a square-core optical fiber coupled to the photosensitive device and configured to guide the second portion of the radiation to the photosensitive device and to homogenize the guided second portion of the radiation such that an intensity cross-section of the received second portion of the radiation at the second photosensitive device is approximately uniform.

6. The apparatus of claim 1, wherein a power-to-phase conversion factor of the detector is less than approximately 1 rad/W.

7. The apparatus of claim 1, wherein the square-core optical fiber has a length of approximately 1-100 m, 1-50 m, 1-20 m, 1-10 m, 1-5 m, 1 m, 5 m, or 10 m.

8. An inspection system comprising:
a radiation source configured to generate radiation;
an optical element configured to direct the radiation toward a target; and
a detector comprising:
a photosensitive device configured to receive at least a portion of radiation scattered by the target and to generate a measurement signal based on the received portion of the radiation; and
a square-core optical fiber coupled to the photosensitive device and configured to guide the portion of the radiation to the photosensitive device and to homogenize the guided portion of the radiation such that an intensity cross-section of the received portion of the radiation at the photosensitive device is approximately uniform.

9. The inspection system of claim 8, wherein the square-core optical fiber is further configured to allow approximately lossless transmission of a plurality of wavelengths of the received portion of the radiation.

10. The inspection system of claim 8, wherein:
the inspection system comprises a digital board; and
the detector is disposed on the digital board.

11. The inspection system of claim 10, wherein:
the board comprises an optical fiber connector;
the square-core optical fiber comprises an optical fiber connector; and
the optical fiber connectors of the board and the square-core optical fiber are configured to mate to achieve the coupling of the square-core optical fiber and the photosensitive device.

12. The inspection system of claim 8, further comprising a second detector comprising:
a second photosensitive device configured to receive a second portion of the radiation scattered by the target and to generate a measurement signal based on the received second portion of the radiation; and
a square-core optical fiber coupled to the photosensitive device and configured to guide the second portion of the radiation to the photosensitive device and to homogenize the guided second portion of the radiation such that an intensity cross-section of the received second portion of the radiation at the second photosensitive device is approximately uniform.

13. A detector comprising:
a photosensitive device configured to receive radiation and to generate a measurement signal based on the received radiation; and
a square-core optical fiber coupled to the photosensitive device and configured guide the radiation scattered by the target to the photosensitive device and to homogenize the guided radiation such that an intensity cross-section of the received radiation at the photosensitive device is approximately uniform.

14. The detector of claim 13, wherein the square-core optical fiber is further configured to allow approximately lossless transmission of a plurality of wavelengths of the received radiation.

15. The detector of claim 14, wherein:
the digital board comprises an optical fiber connector;
the square-core optical fiber comprises an optical fiber connector; and
the optical fiber connectors of the digital board and the square-core optical fiber are configured to mate to achieve the coupling of the square-core optical fiber and the photosensitive device.
